(19) United States
(12) Patent Application Publication
(10) Pub. No.: US 2024/0259715 A1
(43) Pub. Date: Aug. 1, 2024

(54) IMAGE SENSOR

(71) Applicant: Samsung Electronics Co., Ltd., Suwon-si (KR)

(72) Inventors: Changhyung CHOI, Suwon-si (KR); Jaehong KIM, Suwon-si (KR); Jinwoo KIM, Suwon-si (KR); Daehwa PAIK, Suwon-si (KR)

(73) Assignee: Samsung Electronics Co., Ltd., Suwon-si (KR)

(21) Appl. No.: 18/450,813

(22) Filed: Aug. 16, 2023

(30) Foreign Application Priority Data
Jan. 30, 2023 (KR) 10-2023-0011664

(51) Int. Cl. H04N 25/78; H03M 1/56; H04N 17/00

(52) U.S. Cl. CPC H04N 25/78; H03M 1/56; H04N 17/002

(57) ABSTRACT

An image sensor is provided. The image sensor according to an example embodiment includes a pixel array including a plurality of pixels, a ramp signal generator configured to generate a ramp signal that increases or decreases with a constant slope, a signal selector configured to output the ramp signal and one of a pixel signal and a test signal output from the pixel array, and a comparison circuit configured to receive the ramp signal and the test signal from the signal selector during a first period, output a first comparison result of the ramp signal and the test signal, receive the pixel signal and the ramp signal from the signal selector during a second period after the first period, and output a second comparison result of the pixel signal and the ramp signal.

### CROSS-REFERENCE TO RELATED APPLICATION

This application is based on and claims priority under 35 U.S.C. § 119 to Korean Patent Application No. 10-2023-0011664 filed on Jan. 30, 2023, in the Korean Intellectual Property Office, the disclosure of which is incorporated by reference herein in its entirety.

### BACKGROUND

### (1) Field

The disclosure relates to an image sensor.

### (2) Description of Conventional Arts

An image sensor is a device that captures a two-dimensional or three-dimensional image of an object.

The image sensor generates an image of the object using a photoelectric conversion element that reacts according to the intensity of light reflected from the object.

Recently, with the development of CMOS (Complementary Metal-Oxide Semiconductor) technology, CMOS image sensors are widely used. The CMOS image sensor includes pixels composed of CMOS transistors, and converts light energy into an electrical signal using a photoelectric conversion element included in each pixel. An analog-to-digital converter (ADC) receives an analog input voltage generated from the pixel and converts the analog input voltage into a digital signal. The ADC may include a plurality of comparators that compare a rising or falling ramp signal with a constant slope and the analog input voltage. The ramp signal may be generated by a plurality of ramp signal generators.

### SUMMARY

Provided is an image sensor configured to measure the linearity of each comparator in the ADC.

Also provided is an image sensor configured to reduce variation between ramp signals.

According to an example embodiment, there is provided an image sensor comprising a pixel array including a plurality of pixels, a ramp signal generator configured to generate a ramp signal that increases or decreases with a constant slope, a signal selector configured to output the ramp signal and one of a pixel signal and a test signal output from the pixel array, and a comparison circuit configured to receive the ramp signal and the test signal from the signal selector during a first period, output a first comparison result of the ramp signal and the test signal, receive the pixel signal and the ramp signal from the signal selector during a second period after the first period, and output a second comparison result of the pixel signal and the ramp signal.

According to an example embodiment, there is provided an analog-to-digital conversion circuit, comprising a signal selector configured to transfer a test signal and a ramp signal from a ramp signal generator during a first period, and transfer a pixel signal from a pixel array and the ramp signal during a second period after the first period and a comparison circuit configured to receive the ramp signal and the test signal during the first period, output a first comparison result of the ramp signal and the test signal, receive the pixel signal and the ramp signal from the signal selector during the second period, and output a second comparison result of the pixel signal and the ramp signal.

According to an example embodiment, there is provided a method of operating an image sensor, comprising measuring a second ramp signal having a first level based on the first ramp signal increasing or decreasing with a constant slope, determining a compensation value of the first ramp signal based on a measurement result of the second ramp signal, receiving a pixel signal from a pixel array, and generating image data based on the first ramp signal and the pixel signal compensated with the compensation value.

### BRIEF DESCRIPTION OF THE DRAWINGS

FIG. 1 is a block diagram of an image processing block according to an example embodiment.

FIG. 2 is a block diagram of an image sensor according to an example embodiment.

FIG. 3 is a circuit diagram illustrating pixels of an image sensor according to an example embodiment.

FIG. 4 is a block diagram illustrating an ADC of an image sensor according to an example embodiment.

FIG. 5 is a timing diagram illustrating signals applied to an ADC of an image sensor according to an example embodiment.

FIG. 6 is a block diagram of an image sensor according to an example embodiment.

FIG. 7 is a block diagram illustrating an ADC of an image sensor according to an example embodiment.

FIG. 8 is a timing diagram illustrating signals applied to an ADC of an image sensor according to an example embodiment.

FIG. 9 is a block diagram illustrating a ramp signal generator of an image sensor according to an example embodiment.

FIG. 10 is a circuit diagram illustrating a ramp signal generator according to an example embodiment.

FIG. 11 is a flowchart illustrating a method of operating an image sensor according to an example embodiment.

FIG. 12 is a block diagram of an electronic device having a multi-camera module including an image sensor according to an example embodiment.

FIG. 13 is a block diagram showing the camera module of FIG. 12 in detail.

### DETAILED DESCRIPTION

In the following detailed description, certain example embodiments of the present inventive concepts have been shown and described, simply by way of illustration. As those skilled in the art would realize, the described example embodiments may be modified in various different ways, all without departing from the spirit or scope of the present inventive concepts.

Accordingly, the drawings and description are to be regarded as illustrative in nature and not restrictive. Like reference numerals designate like elements throughout the specification. In the flowchart described with reference to the drawing, the order of operations may be changed, several operations may be merged, a certain operation may be divided, and a specific operation may not be performed.

In addition, expressions written in the singular may be interpreted as singular or plural, unless explicit expressions such as “one” or “single” are used. Terms containing ordinal numbers, such as first and second, may be used to describe various configurations elements, but constituent elements are not limited by these terms. These terms may be used for the purpose of distinguishing one constituent element from another constituent element.

As described herein, an element that is “on” another element may be above or beneath or adjacent (e.g., horizontally adjacent) to the other element. An element that is on another element may be directly on the other element, such that the element is in direct contact with the other element. An element that is on another element may be indirectly on the other element, such that the element is isolated from direct contact with the other element by one or more interposing spaces and/or structures.

It will be understood that elements and/or properties thereof may be recited herein as being “the same” or “equal” as other elements, and it will be further understood that elements and/or properties thereof recited herein as being “identical” to, “the same” as, or “equal” to other elements may be “identical” to, “the same” as, or “equal” to or “substantially identical” to, “substantially the same” as or “substantially equal” to the other elements and/or properties thereof. Elements and/or properties thereof that are “substantially identical” to, “substantially the same” as or “substantially equal” to other elements and/or properties thereof will be understood to include elements and/or properties thereof that are identical to, the same as, or equal to the other elements and/or properties thereof within manufacturing tolerances and/or material tolerances. Elements and/or properties thereof that are identical or substantially identical to and/or the same or substantially the same as other elements and/or properties thereof may be structurally the same or substantially the same, functionally the same or substantially the same, and/or compositionally the same or substantially the same.

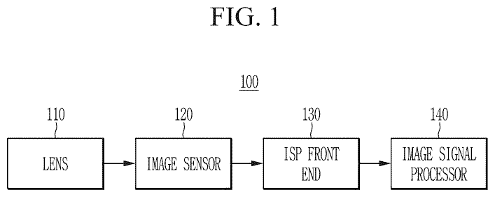

FIG. 1 is a block diagram of an image processing block according to an example embodiment.

Referring to FIG. 1, the image processing block 100 can be implemented as a part of various electronic devices such as a camera, smart phone, wearable device, Internet of Things (IoT), tablet PC (Personal Computer), PDA (Personal Digital Assistant), PMP (Portable Multimedia Player), navigation devices, and the like. In addition, the image processing block 100 may be mounted on electronic devices provided as parts of vehicles, furniture, manufacturing facilities, doors, various measuring devices, and the like.

The image processing block 100 may include a lens 110, an image sensor 120, an image signal processor (ISP) front end 130, and an image signal processor 140.

Light may be reflected by an object or scenery to be photographed, and the lens 110 may receive the reflected light. The image sensor 120 may generate an electrical signal based on light received through the lens 110. For example, the image sensor 120 may be implemented as a complementary metal oxide semiconductor (CMOS) image sensor or the like. In some example embodiments, the image sensor 120 may be a multi-pixel image sensor having a dual pixel structure or a tetra cell structure.

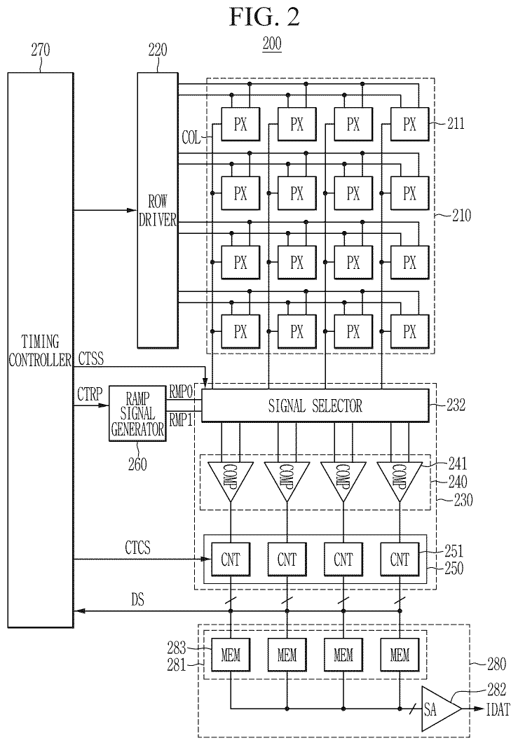

The image sensor 120 may include a pixel array. The pixels of the pixel array may generate pixel values by converting light into an electrical signal. Furthermore, the image sensor 120 may include an analog digital converter (ADC) for performing correlation double sampling (CDS) on pixel values. The configuration of the image sensor 120 will be described in more detail with reference to FIG. 2.

The ISP front end 130 may perform preprocessing on the electrical signals output from the image sensor 120 in a form suitable for processing by the image signal processor 140.

The image signal processor 140 may appropriately process the electrical signal processed by the ISP front end 130 to generate image data related to a photographed object or landscape. To this end, the image signal processor 140 may perform various processing such as color correction, auto white balance, gamma correction, color saturation correction, bad pixel correction, and hue correction.

FIG. 1 illustrates one lens 110, and one image sensor 120. However, in other example embodiments, the image processing block 100 may include multiple lenses, multiple image sensors, and multiple ISP front end blocks. In this case, the plurality of lenses may have different angles of view. Also, the plurality of image sensors may have different functions, different capabilities, and/or different characteristics, and may include different configurations of pixel arrays.

FIG. 2 is a block diagram of an image sensor according to an example embodiment.

Referring to FIG. 2, the image sensor 200 includes a pixel array 210, a row driver 220, an ADC 230, a ramp signal generator 260, a timing controller 270, and a buffer 280.

The pixel array 210 may include a plurality of pixels 211 each connected to a plurality of row lines and a plurality of column lines COL and arranged in a matrix form. Each of the plurality of pixels 211 may include at least one light sensing element. For example, the photo-sensing device may include a photo diode, a photo transistor, a port gate or a pinned photo diode. In some example embodiments, each of the plurality of pixels 211 may include a plurality of light sensing elements. A plurality of photo-sensing elements may be stacked on top of each other.

The plurality of pixels 211 may sense light using a light sensing element and convert the sensed light into an electrical signal, e.g., a pixel signal. Each of the plurality of pixels 211 may sense light in a specific spectral region. For example, the plurality of pixels 211 may include red pixels for converting light in the red spectral region into an electrical signal, green pixels for converting light in the green spectral region into an electrical signal, and blue pixels for converting light in the blue spectral region into an electrical signal. A color filter for transmitting light in a specific spectral region may be disposed above each of the plurality of pixels 211. The pixel signal may include a reset signal generated according to a reset operation of each of the plurality of pixels 211 and may include an image signal according to a light sensing operation of each of the plurality of pixels 211.

The timing controller 270 may control the operation or timing of the low driver 220, the ADC 230, and the ramp signal generator 260 by outputting a control signal or clock signal to each of the low driver 220, the ADC 230, and the ramp signal generator 260.

The row driver 220 may drive the pixel array 210 row by row. The low driver 220 may decode a row control signal (e.g., an address signal) generated by the timing controller 270, and select at least one row line among the row lines comprising the pixel array 210 in response to the decoded row control signal. For example, row driver 220 may generate a row select signal. The pixel array 210 may output pixel signals from a row selected by a row selection signal provided from the row driver 220.

The ADC 230 may convert a pixel signal that is an analog signal input from the pixel array 210 into a digital signal. The ADC 230 may include a signal selector 232, a comparator circuit 240, and a counter circuit 250.

The signal selector 232 may receive the ramp signals RMP0 and RMP1 from the ramp signal generator 260 and a pixel signal from the pixel array 210. The signal selector 232 may operate based on the selection control signal CTSS provided from the timing controller 270. During the image sensing period, the signal selector 232 may output a pixel signal and ramp signals RMP0 and RMP1 to the comparison circuit 240 by the selection control signal CTSS. During the image sensing period, the slopes of the ramp signals RMP0 and RMP1 output from the signal selector 232 may be the same or different from each other. During the test period, the signal selector 232 may output only the ramp signals RMP0 and RMP1 to the comparison circuit 240 by the selection control signal CTSS. During the test period, one of the ramp signals RMP0 and RMP1 output from the signal selector 232 may have a predetermined or alternatively, a desired voltage level, and the other may decrease or increase with a predetermined or alternatively, a desired slope.

The comparison circuit 240 may compare a pixel signal output from a unit pixel connected to any one of the column lines COL constituting the pixel array 210 with one of the ramp signals RMP0 and RMP1. The comparison circuit 240 may include a plurality of comparison circuits 241, each of the plurality of comparison circuits 241 may be connected to a corresponding at least one column line of the plurality of column lines COL via the signal selector 232. Each of the plurality of comparison circuits 241 may be connected to the ramp signal generator 260 through the signal selector 232.

The comparison circuit 241 may receive the pixel signal generated by the pixel array 210 and one of the ramp signals RMP0 and RMP1 generated by the ramp signal generator 260, compare the pixel signal and one of the ramp signals RMP0 and RMP1, and output a comparison result signal.

In an example embodiment, during an image sensing period, the comparison circuit 241 may be connected to a corresponding one column line COL, receive a pixel signal, via the signal selector 232, from the corresponding one column line COL, and receive a corresponding one of the ramp signals RMP0 and RMP1 from the ramp signal generator 260. For example, the comparison circuit 241 may compare the pixel signal and the ramp signal RMP0 and output a comparison result signal.

In an example embodiment, during the test period, the comparison circuit 241 may receive the ramp signals RMP0 and RMP1 from the ramp signal generator 260 through the signal selector 232. The comparison circuit 241 may output a result of comparing the ramp signal RMP0 and the ramp signal RMP1. In some example embodiments, the linearity of the comparison circuit 241 may be measured based on a comparison of the ramp signal RMP0, which decreases with a constant slope, and the ramp signal RMP1, which changes in voltage level by at least one step for each measurement. For example, if the ramp signal RMP1 is decremented by one step for each measurement and compared to the ramp signal RMP0, a comparison result signal corresponding to the difference between the two input voltages of the comparison circuit 241 may be provided to the counter circuit 250.

The comparison circuit 241 may generate a comparison result signal to which a correlated double sampling technique is applied, and may be referred to as a correlated double sampling circuit. The pixel signals output from the plurality of pixels 211 may have deviations due to inherent characteristics of each pixel (e.g., fixed pattern noise (FPN), etc.) and/or deviations due to differences in the characteristics of the logic for outputting the pixel signals from the pixels 211. To compensate for the deviations between these pixel signals, a reset component (or reset signal) and an image component (or image signal) are obtained for each of the pixel signals, and the difference of these two components is extracted as a valid signal component, which is called correlated double sampling. The comparison circuit 241 may output a comparison result signal to which a correlated double sampling technique is applied.

The ramp signal generator 260 may generate ramp signals RMP0 and RMP1. For example, the ramp signal generator 260 may generate decreasing ramp signals RMP0, RMP1 with a constant slope, or may generate reverse ramp signals RMP0, RMP1 with an increasing slope. The ramp signal generator 260 may operate based on the ramp control signal CTRP provided from the timing controller 270. The ramp control signal CTRP may include a ramp enable signal and a mode signal. When the ramp enable signal is activated, the ramp signal generator 260 may generate ramp signals RMP0 and RMP1 based on the mode signal. For example, in the first mode, the ramp signal generator 260 may generate ramp signals RMP0 and RMP1 that decrease with the same slope. In the second mode, the ramp signal generator 260 may generate a ramp signal RMP0 that decreases with a first slope and a ramp signal RMP1 that decreases with a second slope steeper than the first slope. In the third mode, the ramp signal generator 260 may generate a ramp signal RMP0 that decreases with a third slope and a ramp signal RMP1 whose voltage value is changed in units of at least one step. Here, one step unit may be a voltage level that the ramp signal generator 260 can control. For example, when the ramp signal generator 260 controls the ramp signals RMP0 and RMP1 to a voltage level of 0.1 mV, one step unit may be 0.1 mV.

During the image sensing period, the ramp signal generator 260 may operate in the first mode and the second mode. During the test period, the ramp signal generator 260 may operate in the third mode.

The counter circuit 250 may include a plurality of counters 251. Each of the plurality of counters 251 may be connected to an output terminal of the comparison circuit 241 and count an output signal of each comparison circuit 241. The counter control signals CTCS may include a counter clock signal, a counter reset signal that controls a reset operation of the plurality of counters 251, and an inversion signal that inverts an internal bit of each of the plurality of counters 251. The counter circuit 250 may count the comparison result signal based on the counter clock signal and output the counting result as a digital signal DS.

The counter 251 may include an up/down counter and a bit-wise inversion counter. At this time, the bit-wise counter may perform an operation similar to that of the up/down counter. For example, the bit-wise counter may perform a function of performing only up-counting and a function of converting all internal bits of the counter to obtain the 1's complement when a specific signal is received. The bit-wise counter may perform a reset count and may then invert a result of the reset count to the 1's complement, in other words, a negative value.

In an example embodiment, during the test period, the counter 251 may count the comparison result signal output from the corresponding comparison circuit 241 and output it as a digital signal DS. The digital signal DS may be provided to the timing controller 270 or externally output as an image signal IDAT. Accordingly, the linearity of each of the comparison circuits 241 may be measured based on a result output from the comparison circuit 241 and provided to the outside.

However, the image sensor 200 according to the present inventive concepts is not limited thereto. The image sensor 200 may also include a counting code generator generating a counting code under the control of the timing controller 270. The counting code generator may be implemented as a gray code generator and may generate a plurality of code values having a resolution according to a set number of bits as counting codes. For example, the plurality of counters 251 may include a latch circuit and an operation circuit, and the latch circuit may receive a counting code from the counting code generator and an output signal from the comparison circuit 240, and may latch a code value of the counting code at a time when the level of the comparison signal transitions. The operation circuit may compute the reset value and the image signal value and generate an image signal value from which the reset level of the pixel 211 is removed. The counter circuit 250 may output the image signal value from which the reset level is removed as a pixel value.

In an example embodiment, the timing controller 270 may control the ramp signal generator 260 based on the digital signal DS received from the counter circuit 250 during the test period. The timing controller 270 may determine a deviation between the ramp signal RMP0 and the ramp signal RMP1 using the digital signal DS output from the counter 251 and generate the ramp control signal CTRP. The timing controller 270 may determine a compensation value of the ramp signal RMP0 based on a difference between the ramp signal RMP0 and the ramp signal RMP1. In some example embodiments, the timing controller 270 may control the slope of the ramp signals RMP0 and RMP1, the current magnitude of the current source included in the ramp signal generator 260, and the like, based on the deviation of the ramp signal RMP0 from the ramp signal RMP1.

The buffer 280 can temporarily store, amplify, and output the digital signal output from the ADC 230. The buffer 280 may include a column memory block 281 and a sense amplifier 282, and the column memory block 281 may include a plurality of memories 283. Each of the plurality of memories 283 temporarily may store digital signals output from each of the plurality of counters 251 and output the digital signals to a sense amplifier 282, the sense amplifier 282 may sense and amplify the digital signals output from the plurality of memories 283. The sense amplifier 282 may output the amplified digital signals as image data IDAT.

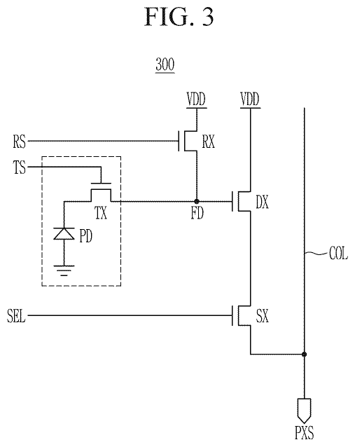

FIG. 3 is a circuit diagram illustrating pixels of an image sensor according to an example embodiment.

Referring to FIG. 3, the pixel 300 includes a photodiode PD, a transfer transistor TX, a floating diffusion node FD, a reset transistor RX, a drive transistor DX, and a select transistor SX. The photodiode PD may be replaced with another photoelectric conversion device.

A photodiode (PD) may generate a photoelectric charge that varies with the intensity of the incident light. The transfer transistor TX may transfer the photoelectric charge to the floating diffusion node FD according to the transfer control signal TS output from the low driver (220 in FIG. 2). According to the potential due to the accumulated photoelectric charge in the floating diffusion node FD, the drive transistor DX may amplify and transmit the photoelectric charge to the select transistor SX. The drain of the select transistor SX is connected to the source of the drive transistor DX, and the select transistor SX may output a pixel signal PXS to the column line COL connected to the pixel 300 according to the select signal SEL output from the low driver 220. The reset transistor RX may reset the floating diffusion node FD to the power supply voltage VDD level according to the reset control signal RS provided from the row driver 220.

While FIG. 3 illustrates a pixel 300 in a four-transistor (4T) structure that includes a photodiode PD and four transistors TX, RX, DX, and SX, each of the plurality of pixels 300 included in an image sensor according to the present disclosure is not limited to the structure of FIG. 3. The pixel 300 may be a pixel in a three-transistor 3T structure, may include a photodiode PD, and may include three transistors selected from a transfer transistor TX, a reset transistor RX, a drive transistor DX, and a select transistor SX. In some example embodiments, the pixel 300 may include a plurality of photodiodes PD and a transfer transistor TX connected to the plurality of photodiodes PD. Also, the pixel 300 may include a plurality of floating diffusion nodes FD.

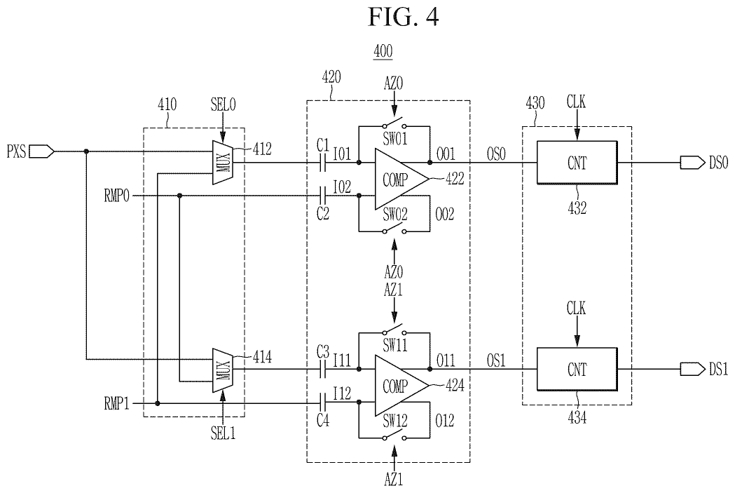

FIG. 4 is a block diagram illustrating an ADC of an image sensor according to an example embodiment.

Referring to FIG. 4, the ADC 400 may include a signal selector 410, a comparison circuit 420, and a counter circuit 430. An output terminal of the signal selector 410 may be connected to an input terminal of the comparison circuit 420, and an output terminal of the comparison circuit 420 may be connected to an input terminal of the counter circuit 430. In FIG. 4, a pixel signal (PXS) from a single column line is shown being applied to the input of the signal selector 410, but a plurality of pixel signals PXS from a plurality of column lines may be applied to the input of the signal selector 410. During the image sensing period, the ramp signal RMP0 and the ramp signal RMP1 may have different slopes.

In an example embodiment, the signal selector 410 may receive the selection signals SEL0 and SEL1 as selection control signals (CTSS in FIG. 2) from the timing controller (270 in FIG. 2). The signal selector 410 may include multiplexers 412 and 414. The multiplexer 412 may receive the pixel signal PXS and the ramp signal RMP1 and output the pixel signal PXS or the ramp signal RMP1 based on the selection signal SEL0. The multiplexer 414 may receive the pixel signal PXS and the ramp signal RMP0, and output the pixel signal PXS or the ramp signal RMP0 based on the selection signal SEL1. In some example embodiments, during the test period, the select signal SEL0 may be applied at an enable level to measure the linearity of the comparator 422 or to measure the characteristics of the ramp signal RMP0. During the test period, the select signal SEL1 may be applied at an enable level to measure the linearity of the comparator 424 or to measure the characteristics of the ramp signal RMP1.

The comparison circuit 420 may include a first comparator 422, a second comparator 424, capacitors C1, C2, C3, and C4, and switches SW01, SW02, SW11, and SW12. The first comparator 422 and the second comparator 424 may include a differential amplifier, which may be implemented as an operational transconductance amplifier (OTA), an operational amplifier, or the like.

The first input end I01 of the first comparator 422 may receive a pixel signal PXS or a ramp signal RMP1 output from the multiplexer 412 via capacitor C1, and the second input end I02 of the first comparator 422 may receive a ramp signal RMP0 via capacitor C2. The first comparator 422 compares the two signals PXS and RMP0 or RMP1 and RMP0 received through the first input terminal I01 and the second input terminal I02, and output the comparison result as an output signal OS0 via the first output terminal O01. The first output terminal O01 and the first input terminal I01 may be connected through the switch SW01, and the second output terminal O02 and the first input terminal I02 may be connected through the switch SW02.

A first input end I11 of the second comparator 424 may receive a pixel signal PXS or a ramp signal RMP0 output from the multiplexer 414 via capacitor C3, and the second input end I12 of the second comparator 424 may receive the ramp signal RMP1 through the capacitor C4. The second comparator 424 compares the two signals PXS and RMP1 or RMP0 and RMP1 received through the first input terminal I11 and the second input terminal I12, and output the comparison result as an output signal OS1 via the first output terminal O11. The first output terminal O11 and the first input terminal I11 may be connected through the switch SW11, and the second output terminal O12 and the first input terminal I12 may be connected through the switch SW12.

The first comparator 422 and the second comparator 424 may be initialized in response to auto-zero signals AZ0 and AZ1 before a comparison operation is performed. In some example embodiments, the first comparator 422 and the second comparator 424 may be initialized in response to the enable-level auto-zero signals AZ0 and AZ1, respectively. For example, when an enable-level auto-zero signal AZ0 is applied to the switch SW01, the input node I01 and the output node O01 of the first comparator 422 may be connected to each other so that the voltage levels of the two nodes are equalized, and when the enable level auto-zero signal AZ0 is applied to the switch SW02, the input node I02 and the output node O02 of the first comparator 422 may be connected to each other so that the voltage levels of the two nodes are equalized.

The counter circuit 430 may include a counter 432 connected to the first output terminal O01 of the first comparator 422 and a counter 434 connected to the first output terminal O11 of the second comparator 424. The counter 432 may count the comparison result signal, that is, the output signal OS0 of the first comparator 422, based on the counting clock signal CLK, and output the digital signal DS0. The counter 434 may count the comparison result signal, that is, the output signal OS1 of the second comparator 424, based on the counting clock signal CLK, and output the digital signal DS1. The counter circuit 430 may transmit the digital signals DS0, DS1 to the buffer (280 in FIG. 2).

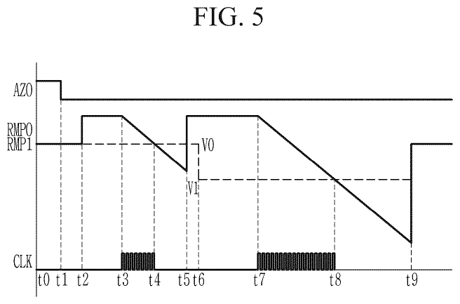

FIG. 5 is a timing diagram illustrating signals applied to an ADC of an image sensor according to an example embodiment.

Referring to FIG. 5, from t0 to t1 may be defined as an auto-zero interval, and from t1 to t9 may be defined as a comparative behavior interval. Before t0, the selection signal SEL may be activated, and the pixel signal PXS may be output from the plurality of pixels 211 of the pixel array 210 of FIG. 2. Also, the power supply voltage VDD may be provided by the reset signal RS activated before t0. Hereinafter, an operation of the ADC 400 measuring the linearity of the first comparator 422 or the characteristics of the ramp signal RMP0 during the test period will be described with reference to FIG. 4 together with FIG. 5.

The auto zero signal AZ0 may be activated from t0 to t1, and the first comparator 422 may be initialized in response to the auto zero signal AZ0.

An offset may be applied to the ramp signal RMP0 at t2, and the ramp signal RMP0 may decrease from t3. The ramp signal RMP1 may maintain the initial level V0. The counter 432 may count the counting clock signal CLK from t3 to t4 when the polarity of the output signal OS0, which is an output of the first comparator 422, changes.

When the digital conversion of the ramp signal RMP1 of the initial level V0 of the first comparator 422 is completed, an offset may be applied to the ramp signal RMP0 again at t5, and at t6, the ramp signal RMP1 may be changed to the first level V1.

At t7, the level of the ramp signal RMP0 may start to decrease. The counter 432 may count the counting clock signal CLK from t7 to t8 when the polarity of the output signal OS0, which is an output of the first comparator 422, changes. Accordingly, the ramp signal RMP1 of the first level V1 can be converted into a digital signal.

Linearity of the first comparator 422 may be measured based on a value obtained by performing correlated double sampling on the initialization level V0 and the ramp signal RMP1 of the first level V1. In some example embodiments, the linearity of the first comparator 422 may be measured by adjusting the level of the ramp signal RMP1, which is changed at the point of t6, in units of 1 step at every measurement. For example, in the first measurement, based on the difference between the CDS value of the ramp signal RMP1 of the first level V1 and the CDS value of the ramp signal RMP1 of the second level lower than the first level V1 by one step, a change in the output value of the first comparator 422 corresponding to one step of the ramp signal RMP1 may be calculated.

The operation in the test period for measuring the linearity of the first comparator 422 or the characteristics of the ramp signal RMP0 described with reference to FIG. 5 may be equally applied to the second comparator 424. Then, the linearity of the second comparator 422 can be measured.

Conventionally, a test device external to the image sensor 200 provides a test signal to the comparison circuit 420. Since the test signal is received through a pad of the image sensor 200 and includes noise, it is difficult to accurately measure the linearity of the comparators. The image sensor 200 according to an example embodiment may accurately measure the linearity of the comparators of the comparison circuit 420 using the internal ramp signal generator 260. In addition, according to an example embodiment, since the ramp signals RMP0, RMP1, can be adjusted in the control unit of the ramp signal generator 260, e.g., one-step unit, and thus the linearity of the comparators of the comparison circuit 420 can be accurately measured.

In some example embodiments, when the linearity of the first comparator 422 and the second comparator 424 are substantially the same, based on the change in the output value of the first comparator 422 corresponding to one step of the ramp signal RMP1 and the change in the output value of the second comparator 424 corresponding to one step of the ramp signal RMP0, deviations of the ramp signals RMP0 and RMP1 may be measured.

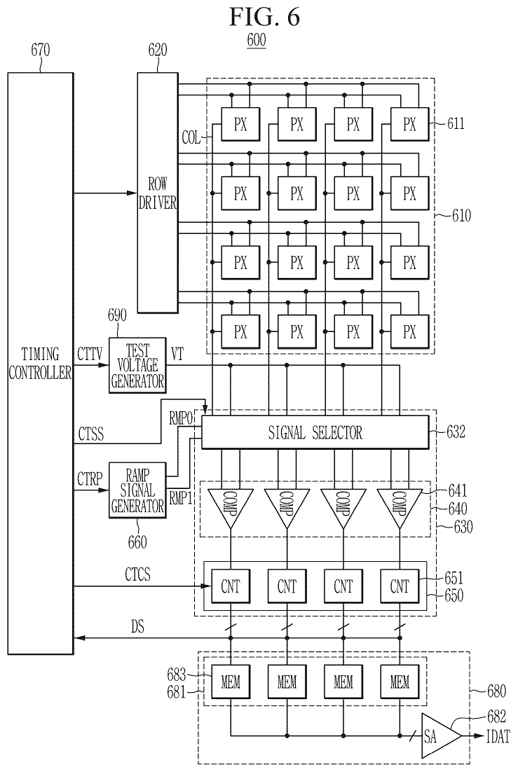

FIG. 6 is a block diagram of an image sensor according to an example embodiment.

Referring to FIG. 6, an image sensor 600 includes a pixel array 610, a row driver 620, an ADC 630, a ramp signal generator 660, a timing controller 670, a buffer 680, and a test voltage. generator 690. Hereinafter, descriptions of elements of FIG. 6 that are the same as or similar to those of the image sensor 200 of FIG. 2 will be omitted.

The signal selector 632 may receive input ramp signals RMP0, RMP1 from the ramp signal generator 660, input pixel signals from the pixel array 610, and input test signals VT from the test voltage generator 690. The signal selector 232 may operate based on the selection control signal CTSS provided from the timing controller 270. During the image sensing period, the signal selector 632 may output a pixel signal and ramp signals RMP0 and RMP1 to the comparison circuit 640 by the selection control signal CTSS. During the image sensing period, slopes of the ramp signals RMP0 and RMP1 output from the signal selector 632 may be substantially the same or different from each other. During the test period, the signal selector 632 may output the test signal VT and the ramp signals RMP0 and RMP1 to the comparison circuit 640 by the selection control signal CTSS. During the test period, the slopes of the ramp signals RMP0 and RMP1 output from the signal selector 632 may be substantially the same or different from each other. During the test period, the test signal VT output from the signal selector 632 may have a predetermined or alternatively, a desired voltage level.

The comparison circuit 640 may compare a pixel signal output from a unit pixel connected to any one of the column lines COL included in the pixel array 610 with one of the ramp signals RMP0, RMP1. The comparison circuit 640 may include a plurality of comparison circuits 641, and each of the plurality of comparison circuits 641 may be connected to a corresponding at least one column line of the plurality of column lines COL through the signal selector 632. Each of the plurality of comparison circuits 641 may be connected to the ramp signal generator 660 through a signal selector 632.

The comparison circuit 641 may receive the pixel signal generated by the pixel array 610 and one of the ramp signals RMP0, RMP1 generated by the ramp signal generator 660, compare the pixel signal and one of the ramp signals RMP0, RMP1 to each other, and output a comparison result signal. In an example embodiment, during the image sensing period, the comparison circuit 641 may be connected to a corresponding one column line COL via the signal selector 632, to receive a pixel signal, and may receive a corresponding one of the ramp signals RMP0, RMP1 from the ramp signal generator 660. For example, the comparison circuit 641 may compare the pixel signal and the ramp signal RMP0 and output a comparison result signal.

In an example embodiment, during the test period, the comparison circuit 641 may receive the ramp signals RMP0 and RMP1 from the ramp signal generator 660 through the signal selector 632. The comparison circuit 641 may output a result of comparing the ramp signals RMP0 and RMP1 with the test signal VT. In some example embodiments, the linearity of the comparison circuit 641 may be measured based on a comparison of the ramp signal RMP0, which decreases with a constant slope, and the test signal VT, whose voltage value changes by at least one step with each measurement. For example, if the test signal VT is decremented by one step for each measurement and compared to the ramp signal RMP0, a comparison result signal corresponding to the difference between the two input voltages of the comparison circuit 641 may be provided to the counter circuit 650.

The counter 651 may count the comparison result signal output from the corresponding comparison circuit 641 and output the counting result as a digital signal DS. The digital signal DS may be provided to the timing controller 670 or externally output as an image signal IDAT. Accordingly, the linearity of each of the comparison circuits 641 may be measured based on a result output from the comparison circuit 641 and provided to the outside.

The test voltage generator 690 may generate a test signal VT whose voltage value is changed in units of at least one step. Here, one step unit may be a voltage level controllable by the test voltage generator 690. For example, when the test voltage generator 690 controls the test signal VT to a voltage level of 0.1 mV, one step unit may be 0.1 mV.

The test voltage generator 690 may operate based on the test control signal CTTV provided from the timing controller 670. During the test period, the test voltage generator 690 may generate the test signal VT based on the test control signal CTTV and output the test signal VT.

In an example embodiment, the timing controller 670 may control the ramp signal generator 660 based on the digital signal DS received from the counter circuit 650 during the test period. The timing controller 670 may determine a deviation between the ramp signal RMP0 and the ramp signal RMP1 using the digital signal DS output by the counter 651 and generate the ramp control signal CTRP. In some example embodiments, based on the deviation of the ramp signal RMP0 from the ramp signal RMP1, the timing controller 670 may control the slope of the ramp signals RMP0, RMP1, the current magnitude of the current source included in the ramp signal generator 660, or the like.

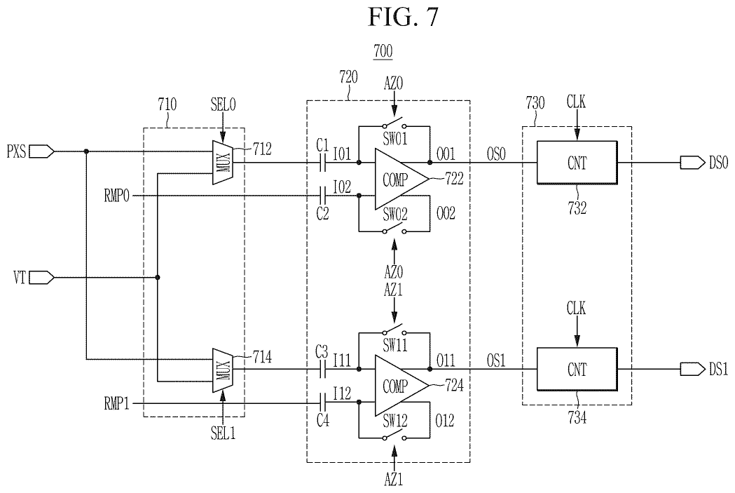

FIG. 7 is a block diagram illustrating an ADC of an image sensor according to an example embodiment.

Referring to FIG. 7, the ADC 700 may include a signal selector 710, a comparison circuit 720, and a counter circuit 730. Hereinafter, descriptions of elements of FIG. 7 that are the same or similar to those of the ADC 400 of FIG. 4 are omitted.

An output terminal of the signal selector 710 may be connected to an input terminal of the comparison circuit 720, and an output terminal of the comparison circuit 720 may be connected to an input terminal of the counter circuit 730. In FIG. 7, a pixel signal (PXS) from a single column line is shown being applied to the input of the signal selector 710, but a plurality of pixel signals (PXS) from a plurality of column lines may be applied to the input of the signal selector 710.

In an example embodiment, the signal selector 710 may receive the selection signals SEL0 and SEL1 as selection control signals (CTSS in FIG. 6) from the timing controller (670 in FIG. 6). Signal selector 710 may include multiplexers 712, 714. The multiplexer 712 may receive the pixel signal PXS and the test signal VT, and output the pixel signal PXS or the test signal VT based on the selection signal SEL0. The multiplexer 714 may receive the pixel signal PXS and the test signal VT, and output the pixel signal PXS or the test signal VT based on the selection signal SEL1. In some example embodiments, during the test period, the selection signal SEL0 may be applied at an enable level to measure the linearity of the comparator 722 or to measure the characteristics of the ramp signal RMP0. During the test period, the select signal SEL1 may be applied at an enable level to measure the linearity of the comparator 724 or the characteristics of the ramp signal RMP1.

The comparison circuit 720 may include a first comparator 722, a second comparator 724, capacitors C1, C2, C3, and C4, and switches SW01, SW02, SW11, and SW12. The first input terminal I01 of the first comparator 722 may receive the pixel signal PXS or the test signal VT output from the multiplexer 712 through the capacitor C1, and the second input terminal I02 of the first comparator 722 may receive the ramp signal RMP0 through the capacitor C2. The first comparator 722 may compare the two signals (PXS and RMP0 or VT and RMP0) received through the first input terminal I01 and the second input terminal I02, and output the comparison result through the first output terminal O01 as an output signal OS0. The first output terminal O01 and the first input terminal I01 may be connected to each other through the switch SW01, and the second output terminal O02 and the first input terminal I02 may be connected to each other through the switch SW02.

The first input terminal I11 of the second comparator 724 may receive the pixel signal PXS or the test signal VT output from the multiplexer 714 through the capacitor C3, and the second input terminal I12 of the second comparator 724 may receive the ramp signal RMP1 through the capacitor C4. The second comparator 724 may compare the two signals (PXS and RMP1 or VT and RMP1) received through the first input terminal I11 and the second input terminal I12, and output the comparison result through the first output terminal O11 as an output signal OS1. The first output terminal O11 and the first input terminal I11 may be connected to each other through the switch SW11, and the second output terminal O12 and the first input terminal I12 may be connected to each other through the switch SW12.

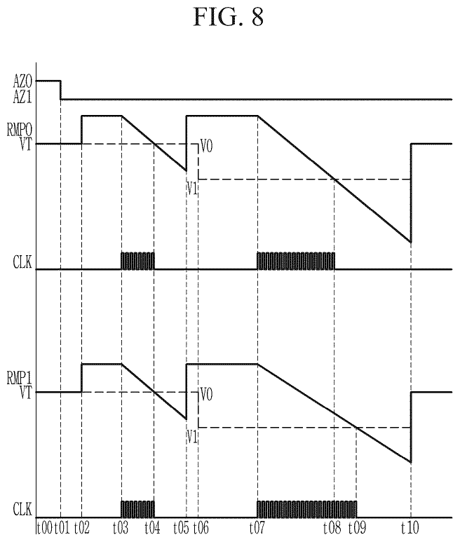

FIG. 8 is a timing diagram illustrating signals applied to an ADC of an image sensor according to an example embodiment.

Referring to FIG. 8, the time from t00 to t01 may be defined as an auto-zero interval, and the time from t01 to t10 may be defined as a comparison operation period. Before t00, the selection signal SEL may be activated, and the pixel signal PXS may be output from the plurality of pixels 611 of the pixel array 610 of FIG. 6. In addition, the power supply voltage VDD may be provided by the reset signal RS activated before t00. Hereinafter, an operation of the ADC 700 measuring the linearity of the first comparator 622 and the linearity of the second comparator 624 or the characteristics of the ramp signals RMP0, RMP1 during the test period will be described with reference to FIG. 7 together with FIG. 8.

The auto zero signals AZ0 and AZ1 may be activated from t00 to t01, and in response to the auto zero signal AZ0, the first comparator 722 is initialized, and in response to the auto zero signal AZ1, A second comparator 724 may be initialized.

An offset may be applied to the ramp signal RMP0 and RMP1 at t02, and the ramp signal RMP0 and RMP1 may decrease from t03. The test signal VT may maintain the initial level V0. The counter 732 may count the counting clock signal CLK from t03 to t04 when the polarity of the output signal OS0, which is an output of the first comparator 722, changes. It is assumed that the polarity of the output signal OS1, which is the output of the second comparator 724, also changes at t04.

When the digital conversion of the test signals VT of the initial level V0 of the first comparator 722 and the second comparator 724 is completed, an offset may be applied to the ramp signals RMP0, RMP1 again at t05, and at t06, the test signal VT may be changed to the first level V1.

At t07, the levels of the ramp signal RMP0 and the ramp signal RMP1 may decrease. The counter 732 may count the counting clock signal CLK from t07 to t08 when the polarity of the output signal OS0, which is an output of the first comparator 722, changes. The counter 734 may count the counting clock signal CLK from t07 to t09 when the polarity of the output signal OS1, which is an output of the second comparator 724, changes. Accordingly, the test signal VT of the first level V1 input to the first comparator 722 and the second comparator 724 may be converted into a digital signal.

Linearity of the first comparator 722 and the second comparator 724 may be measured based on values obtained by performing correlated double sampling on the initialization level V0 and the first level V1 of the test signal VT. In some example embodiments, the linearity of the first comparator 722 and the second comparator 724 may be measured by adjusting the level of the test signal VT, which is changed at t06, in units of 1 step at every measurement. For example, in the first measurement, based on the difference between the CDS value of the test signal VT of the first level V1 and the CDS value of the test signal VT of the second level lower than the first level V1 by one step, changes in the output values of the first comparator 722 and the second comparator 724 corresponding to one step of the ramp signal RMP1 may be calculated.

In some example embodiments, when the linearity of the first comparator 722 and the linearity of the second comparator 724 are substantially the same, based on a change in the output value of the first comparator 722 corresponding to a first step of the test signal VT and a change in the output value of the second comparator 724 corresponding to a first step of the test signal VT, the deviation of the ramp signals RMP0, RMP1 may be measured.

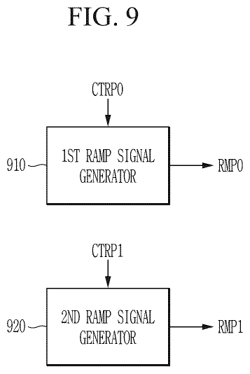

FIG. 9 is a block diagram illustrating a ramp signal generator of an image sensor according to an example embodiment.

Referring to FIG. 9, the ramp signal generator 900 may include a first ramp signal generator 910 and a second ramp signal generator 920.

The first ramp signal generator 910 may receive the ramp control signal CTRP0 from the timing controller (270 in FIGS. 2 and 670 in FIG. 6). The first ramp signal generator 910 may adjust the slope of the ramp signal RMP0 based on the ramp control signal CTRP0 or output a ramp signal RMP0 for a test operation.

The second ramp signal generator 920 may receive the ramp control signal CTRP1 from the timing controllers 270 and 670. The second ramp signal generator 920 may adjust the slope of the ramp signal RMP1 based on the ramp control signal CTRP1 or output the ramp signal RMP1 for a test operation.

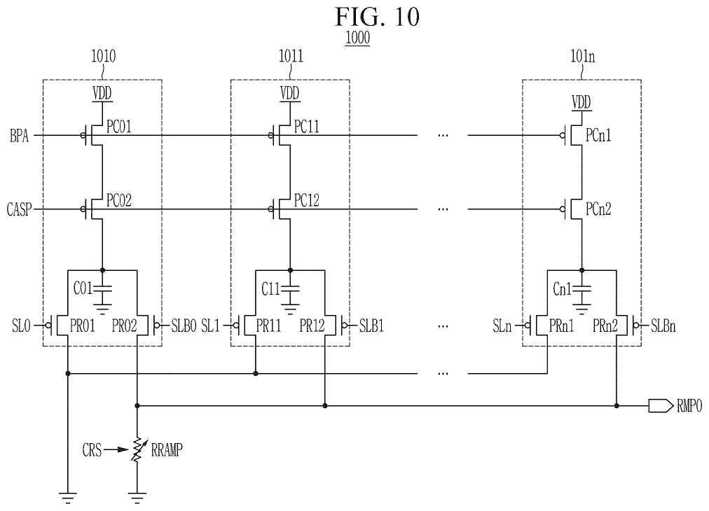

FIG. 10 is a circuit diagram illustrating a ramp signal generator according to an example embodiment.

Referring to FIG. 10, a first ramp signal generator 1000 outputting a ramp signal RMP0 is shown. The first ramp signal generator 1000 may include a plurality of ramp current sources 1010, 1011, . . . , 101n and a ramp resistor RRAMP connected in parallel. The first ramp signal generator 1000 may receive a ramp control signal CTRP1 including control signals BPA, CASP, SL0, SLB0, and CRS.

The ramp current source 1010 includes transistors PC01, PC02, PR01, and PR02 and a capacitor C01, and may operate in response to control signals BPA, CASP, SLB0, and SL0. The transistors PC01 and PC02 and the capacitor C01 may be connected in series between the power supply voltage VDD and the ground voltage. The transistor PR01 may be connected in series between a node between the transistor PC02 and the capacitor C01 and a ground voltage. The transistor PR02 and the ramp resistor RRAMP may be connected in series between the node between the transistor VDD and the capacitor C01 and the ground voltage. Control signals BPA, CASP, SL0, and SLB0 may be applied to gates of the transistors PC01, PC02, PR01, and PR02, respectively.

The remaining ramp current sources 1011, . . . , 101n may have substantially the same structure as the ramp current source 1010. For example, the ramp current source 1011 may include transistors PC11, PC12, PR11, and PR12 and a capacitor C11, and operate in response to control signals BPA, CASP, SL1, and SLB1. The ramp current source 101n includes transistors PCn1, PCn2, PRn1, and PRn2 and a capacitor Cn1, and may operate in response to control signals BPA, CASP, SLn, and SLBn.

The plurality of ramp current sources 1010, 1011, . . . , 101n may be sequentially turned off when the ramp signal RMP0 is desired to be lowered to a preset slope, and may be sequentially turned on when the ramp signal RMP0 is desired to increase to a preset slope.

Specifically, all of the plurality of ramp current sources 1010, 1011, . . . , 101n may be simultaneously turned on at the beginning of operation. When all the ramp current sources 1010, 1011, . . . , 101n are turned on, an offset is applied to the ramp signal RMP0, and the ramp signal RMP0 is to decrease with a constant slope, the ramp current source 1010 may be turned off in response to the control signals SL0 and SLB0, the ramp current source 1011 may be additionally turned off in response to the control signals SL1 and SLB1, and the ramp current source 101n may be additionally turned off in response to the control signals SLn and SLBn. When all of the ramp current sources 1010, 1011, . . . , 101n are turned off, the ramp signal RMP0 may have the lowest voltage level.

Afterwards, when the ramp signal RMP0 is to be increased with the constant slope, the ramp current source 1010 may be turned on in response to the control signals SL0 and SLB0, the ramp current source 1011 may be additionally turned on in response to the control signals SL1 and SLB1, the ramp current source 101n may be additionally turned on in response to the control signals SLn and SLBn. When all of the ramp current sources 1010, 1011, . . . , 101n are turned on, the ramp signal RMP0 may have the highest voltage level.

In an example embodiment, the plurality of ramp current sources 1010, 1011, . . . , 101n may be turned on or off at the same time to generate ramp signals having different slopes. During the test period from t0 to t6, the timing controllers 270 and 670 simultaneously turn on some current sources among the ramp current sources 1010, 1011, . . . , 101n to output the ramp signal RMP0 having the initial level V0, and at t6, the timing controllers 270 and 670 may turn off some of the turned-on current sources to output ramp signal RMP0 having the first level V1.

The ramp resistance RRAMP may be a variable resistor. The timing controllers 270 and 670 may adjust the gain of the ramp signal RMP0 by providing the control signal CRS to the variable resistor and changing the resistance value of the variable resistor RRAMP. For example, as the value of the variable resistance RRAMP increases, the amount of change in the ramp signal RMP0 that changes as the ramp current sources 1010, 1011, . . . , 101n are turned on/off increases.

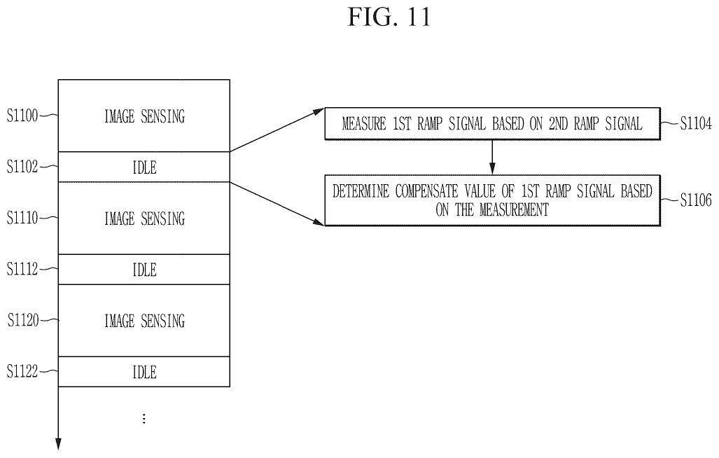

FIG. 11 is a flowchart illustrating a method of operating an image sensor according to an example embodiment.

Referring to FIG. 11, during the image sensing period IMAGE SENSING, the image sensor compares the pixel signal PXS with ramp signals RMP0 and RMP1 to generate image data IDAT (S1100).

During the idle period IDLE during which the image sensor does not generate the image data IDAT, the image sensor measures the ramp signals RMP0 and RMP1 (S1102).

The image sensing period IMAGE SENSING and the idle period IDLE may be alternately performed as in steps S1110, S1112, S1120, and S1122.

During the idle period IDLE, the image sensor measures the second ramp signal RMP1 based on the first ramp signal RMP0 (S1104). The image sensor may measure the second ramp signal RMP1 having a predetermined or alternatively, a desired voltage level based on the first ramp signal RMP0 decreasing/increasing with a predetermined or alternatively, a desired slope. In some example embodiments, the image sensor may repeatedly measure the second ramp signal RMP1 during the idle period IDLE. For every measurement, the level of the second ramp signal RMP1 may be changed in units of at least one step. That is, the level of the first ramp signal RMP0 corresponding to the second ramp signal RMP1, which is changed at every measurement, may be measured.

During the idle period IDLE, the image sensor determines a compensation value of the first ramp signal RMP0 based on the measurement result (S1106). In some example embodiments, the image sensor may calculate a deviation between the second ramp signal RMP1 and the first ramp signal RMP0 based on the measurement result. The image sensor may determine a compensation value of the first ramp signal RMP0 that compensates for a difference between the second ramp signal RMP1 and the first ramp signal RMP0.

Although step S1102 was described as compensating for a deviation of the first ramp signal RMP0 with respect to the second ramp signal RMP1, step S1102 can also be used to compensate for a deviation of the second ramp signal RMP1 with respect to the first ramp signal RMP0.

The image sensor generates image data IDAT based on the compensated first ramp signal RMP0 in the next image sensing period (IMAGE SENSING) (S1110). In some example embodiments, the image sensor may generate image data IDAT by comparing the pixel signal PXS with the compensated first ramp signal RMP0. In some example embodiments, the image sensor may receive a first pixel signal from a first pixel of the plurality of pixels, a second pixel signal from a second pixel of the plurality of pixels, generate first image data based on the first pixel signal and the first ramp signal, and generate second image data based on the second pixel signal and the second ramp signal.

According to an example embodiment, a deviation of the ramp signals RMP0, RMP1 output from the ramp signal generator may be determined using a signal selector of the image sensor, and relatively good quality image data (IDAT) can be obtained using the compensated ramp signals RMP0, RMP1 based on the deviation.

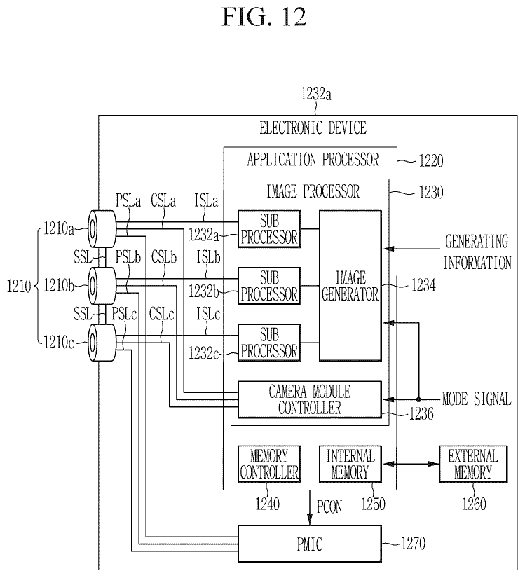

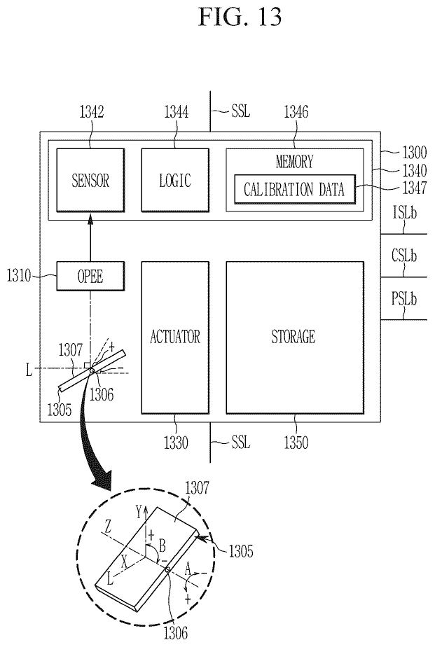

FIG. 12 is a block diagram of an electronic device having a multi-camera module including an image sensor according to an example embodiment, and FIG. 13 is a detailed block diagram of the camera module of FIG. 12.

Referring to FIG. 12, an electronic device 1200 may include a camera module group 1210, an application processor 1220, a PMIC 1270, and an external memory 1260.

The camera module group 1210 may include a plurality of camera modules 1210a, 1210b, and 1210c. Although the drawing shows an example embodiment in which three camera modules 1210a, 1210b, and 1210c are disposed, the example embodiments are not limited thereto. In some example embodiments, the camera module group 1210 may be modified to include only two camera modules. Also, in some example embodiments, the camera module group 1210 may be modified to include n (n is a natural number of 4 or more) camera modules.

Hereinafter, with reference to FIG. 13, the detailed configuration of camera module 1210b will be described more specifically, but the following description may be equally applicable to other camera modules 1210a, 1210c, depending on the example embodiment.

Referring to FIG. 13, a camera module 1300 includes a prism 1305, an optical path folding element (hereinafter referred to as “OPFE”) 1310, an actuator 1330, an image sensing device 1340, and A storage unit 1350 may be included.

The prism 1305 may include a reflective surface 1307 of a light reflective material to change a path of light L incident from the outside.

In some example embodiments, the prism 1305 may change the path of light L incident in the first direction X to a second direction Y perpendicular to the first direction X. In addition, the prism 1305 rotates the reflective surface 1307 of the light reflecting material in the direction A around the central axis 1306 or rotates the central axis 1306 in the direction B to move in the first direction X. A path of the incident light L may be changed in a second direction Y, which is perpendicular to the second direction Y. At this time, the OPFE 1310 may also move in a third direction (Z) perpendicular to the first direction (X) and the second direction (Y).

In some example embodiments, the maximum rotation angle of the prism 1305 in the A direction can be less than or equal to 15 degrees in the plus (+) A direction and greater than 15 degrees in the minus (−) A direction, but example embodiments are not limited thereto.

In some example embodiments, the prism 1305 can be moved in the plus (+) or minus (−) B direction by about 20 degrees, or between 10 and 20 degrees, or between 15 and 20 degrees, where the angle of movement can be the same angle in the plus (+) or minus (−) B direction, or can range from about 1 degree to a nearly similar angle.

In some example embodiments, the prism 1305 can move the reflective surface 1307 of the light reflective material in a third direction (e.g., the Z direction) parallel to the direction of extension of the center axis 1306.

The OPFE 1310 may include, for example, optical lenses consisting of m (where m is a natural number) groups. The m lenses may move in the second direction (Y) to change the optical zoom ratio of the camera module 1210b. For example, assuming that the default optical zoom magnification of the camera module 1210b is Z, if the m optical lenses included in the OPFE 1310 are moved, the optical zoom magnification of the camera module 1210b can be changed to an optical zoom magnification of 3Z or 5Z or 5Z or more. The OPFE 1310 may further include an optical lens consisting of p (where p is a natural number) number of groups on the front side of the aforementioned m number of lenses.

The actuator 1330 may move the OPFE 1310 or an optical lens (hereinafter referred to as an optical lens) to a specific position. For example, the actuator 1330 may adjust the position of the optical lens so that the image sensor 1342 is positioned at the focal length of the optical lens for accurate sensing.

The image sensing device 1340 may include an image sensor 1342, a control logic 1344, and a memory 1346. The image sensor 1342 may sense an image of a sensing target using light L provided through an optical lens. In some example embodiments, the ADC circuit of the image sensor 1342 may use a first ramp signal having a predetermined or alternatively, a desired level or a test signal to measure a second ramp signal that decreases or increases with a predetermined or alternatively, a desired slope during the test period, and may output the measurement results of the second ramp signal to an external source, or may use the measurement results to determine a compensation value for the second ramp signal. Linearity of each of the comparators in the ADC circuit may be measured based on the measurement result of the second ramp signal output from the image sensor 1342. Also, the image sensor 1342 may improve performance degradation of the image sensor 1342 by using the compensated second ramp signal. The control logic 1344 may control overall operations of the camera module 1300. For example, the control logic 1344 may control the operation of the camera module 1300 according to a control signal provided through the control signal line CSLb.

The memory 1346 may store information required for operation of the camera module 1300, such as calibration data 1347. The calibration data 1347 may include information necessary for the camera module 1300 to generate image data using light L provided from the outside. The calibration data 1347 may include, for example, information about a degree of rotation, information about a focal length, information about an optical axis, and the like, as described above, but example embodiments are not limited thereto. If the camera module 1300 is implemented as a multi-state camera where the focal length varies with the position of the optical lens, the calibration data 1347 may include focal length values for each position (or state) of the optical lens and information related to auto focusing.

The storage unit 1350 may store image data sensed through the image sensor 1342. The storage unit 1350 may be disposed outside the image sensing device 1340 and may be implemented in a stacked form with a sensor chip constituting the image sensing device 1340. In some example embodiments, the storage unit 1350 may be implemented as Electrically Erasable Programmable Read-Only Memory (EEPROM), but embodiments are not limited thereto.

Referring to FIGS. 12 and 13 together, in some example embodiments, each of the plurality of camera modules 1210a, 1210b, and 1210c may include an actuator 1330. Accordingly, each of the plurality of camera modules 1210a, 1210b, and 1210c may include the same or different calibration data 1347 according to the operation of the actuator 1330 included therein.

In some example embodiments, one camera module (e.g., 1210b) of the plurality of camera modules 1210a, 1210b, 1210c may be a camera module in the form of a folded lens that includes the previously described prism 1305 and OPFE 1310, and the remaining camera modules (e.g., 1210a, 1210b) may be camera modules in the form of a vertical that does not include the prism 1305 and OPFE 1310, but embodiments are not limited thereto.

In some example embodiments, the camera module (e.g., 1210c) of one of the plurality of camera modules 1210a, 1210b, 1210c may be a depth camera in the form of a vertical that utilizes infrared rays (IR) to extract depth information, for example. In this case, the application processor 1220 may merge the image data provided by these depth cameras with the image data provided by the other camera modules (e.g., 1210a or 1210b) to generate a three-dimensional depth image.

In some example embodiments, at least two camera modules (e.g., 1210a, 1210b) of the plurality of camera modules 1210a, 1210b, 1210c may have different fields of view. In this case, for example, the optical lenses of at least two of the camera modules (e.g., 1210a, 1210b, 1210c) of the plurality of camera modules 1210a, 1210b, 1210c may be different, but are not limited to.

Also, in some example embodiments, each of the plurality of camera modules 1210a, 1210b, and 1210c may have different viewing angles. In this case, optical lenses included in each of the plurality of camera modules 1210a, 1210b, and 1210c may also be different from each other, but are not limited thereto.

In some example embodiments, each of the plurality of camera modules 1210a, 1210b, and 1210c may be disposed physically separated from each other. That is, an independent image sensor 1342 may be disposed inside each of the plurality of camera modules 1210a, 1210b, 1210c, rather than the sensing area of one image sensor 1342 being divided and used by the plurality of camera modules 1210a, 1210b, 1210c.

Referring back to FIG. 12, the application processor 1220 may include an image processing device 1210, a memory controller 1220, and an internal memory 1230. The application processor 1220 may be implemented separately from the plurality of camera modules 1210a, 1210b, and 1210c. For example, the application processor 1220 and the plurality of camera modules 1210a, 1210b, and 1210c may be separately implemented as separate semiconductor chips.

The image processing device 1210 may include a plurality of sub image processors 1232a, 1232b, and 1232c, an image generator 1234, and a camera module controller 1236.

The image processing device 1210 may include a plurality of sub image processors 1232a, 1232b, and 1232c corresponding to the number of the plurality of camera modules 1210a, 1210b, and 1210c.

Image data generated from each of the camera modules 1210a, 1210b, and 1210c may be provided to the corresponding sub image processors 1232a, 1232b, and 1232c through separate image signal lines ISLa, ISLb, and ISLc. For example, image data generated from camera module 1210a may be provided to sub-image processor 1232a via image signal line ISLa, image data generated from camera module 1210b may be provided to sub-image processor 1232b via image signal line ISLb, and image data generated from camera module 1210c may be provided to sub-image processor 1232c via image signal line ISLc. Such image data transmission may be performed using, for example, a Camera Serial Interface (CSI) based on MIPI (Mobile Industry Processor Interface), but example embodiments are not limited thereto.

Image data provided to each of the sub image processors 1232a, 1232b, and 1232c may be provided to the image generator 1234. The image generator 1234 may generate an output image using image data provided by each of sub-image processors 1232a, 1232b, 1232c in accordance with image generating information or a mode signal.

Specifically, image generator 1234 may merge at least some of the image data generated from camera modules 1210a, 1210b, 1210c having different fields of view to generate an output image, based on image generation information or mode signals. Furthermore, the image generator 1234 may select any of the image data generated from the camera modules 1210a, 1210b, 1210c having different fields of view to generate the output image, based on the image generation information or mode signal.

The camera module controller 1236 may provide a control signal to each of the camera modules 1210a, 1210b, and 1210c. Control signals generated from the camera module controller 1236 may be provided to corresponding camera modules 1210a, 1210b, and 1210c through separate control signal lines CSLa, CSLb, and CSLc.

The application processor 1220 may store the received image signal, e.g., the encoded image signal, in an internally provided memory 1230 or in storage 1260 external to the application processor 1220, and may then read the encoded image signal from the memory 1230 or storage 1260, decode the encoded image signal, and display image data generated based on the decoded image signal. For example, a corresponding subprocessor of the plurality of subprocessors 1232a, 1232b, 1232c of the image processing device 1210 may perform decoding, and may also perform image processing on the decoded image signal.

The PMIC 1270 may supply power, e.g., a power supply voltage, to each of the plurality of camera modules 1210a, 1210b, and 1210c. For example, PMIC 1270 may, under the control of application processor 1220, provide first power to camera module 1210a via power signal line PSLa, second power to camera module 1210b via power signal line PSLb, and third power to camera module 1210c via power signal line PSLc.

In some example embodiments, each configuration or combination of two or more configurations described with reference to FIGS. 1 to 13 may be implemented as a digital circuit, a programmable or non-programmable logic device or array, an application specific integrated circuit (ASIC), or the like.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

Although example embodiments of the present inventive concepts have been described in detail above, the scope of the present inventive concepts is not limited thereto, and various modifications and improvements by those skilled in the art utilizing the basic concepts of the present inventive concepts as defined in the following claims are also within the scope of the present inventive concepts.

What is claimed is:

1. An image sensor, comprising:
a pixel array including a plurality of pixels;
a ramp signal generator configured to generate a ramp signal that increases or decreases with a constant slope;
a signal selector configured to output the ramp signal and one of a pixel signal and a test signal output from the pixel array; and
a comparison circuit configured to receive the ramp signal and the test signal from the signal selector during a first period, output a first comparison result of the ramp signal and the test signal, receive the pixel signal and the ramp signal from the signal selector during a second period after the first period, and output a second comparison result of the pixel signal and the ramp signal.

2. The image sensor of claim 1, wherein
the ramp signal generator is configured to generate the test signal during the first period.

3. The image sensor of claim 2, wherein
after the comparison circuit outputs the first comparison result based on the test signal having a first level, the ramp signal generator is configured to adjust the test signal to a second level different from the first level and outputs the test signal to the signal selector.

4. The image sensor of claim 3, wherein
the ramp signal generator includes a plurality of ramp current sources connected in parallel, and is configured to turn on a first ramp current source of the plurality of ramp current sources to output the first level of test signals, and is configured to turn on a second ramp current source of the plurality of ramp current sources that is different from the first ramp current source to output the second level of test signals.

5. The image sensor of claim 1, further comprising:
a timing controller configured to control an operation of the signal selector,
wherein the signal selector is configured to transfer the test signal and the ramp signal in response to a selection signal provided from the timing controller.

6. The image sensor of claim 5, wherein
the timing controller is configured to control an operation of the ramp signal generator during the second period based on the first comparison result.

7. The image sensor of claim 6, further comprising:
a counter circuit configured to output a first counting result to the timing controller based on the first comparison result.

8. The image sensor of claim 1, wherein
the signal selector includes a multiplexer configured to receive the pixel signal and the test signal, output the test signal during the first period, and output the pixel signal during the second period.

9. The image sensor of claim 1, further comprising:
a test signal generator configured to generate the test signal,
wherein the ramp signal generator includes a first ramp signal generator configured to generate a first ramp signal from the ramp signal and a second ramp signal generator configured to generate a second ramp signal that increases or decreases with a predetermined slope, and
wherein the comparison circuit includes a first comparator configured to output the first comparison result of the first ramp signal and the test signal during the first period and a second comparator configured to output a third comparison result of the second ramp signal and the test signal during the first period.

10. The image sensor of claim 9, wherein
the first ramp signal generator is configured to generate a compensated first ramp signal based on the first comparison result during the second period.

11. The image sensor of claim 9, wherein
the first ramp signal generator is configured to generate the first ramp signal having a first slope during the second period,
the second ramp signal generator is configured to generate the second ramp signal having a second slope different from the first slope during the second period,
the first comparator is configured to output the second comparison result during the second period, and
the second comparator is configured to output a fourth comparison result of the pixel signal and the second ramp signal during the second period.

12. An analog-to-digital conversion circuit, comprising:
a signal selector configured to transfer a test signal and a ramp signal from a ramp signal generator during a first period, and transfer a pixel signal from a pixel array and the ramp signal during a second period after the first period; and
a comparison circuit configured to receive the ramp signal and the test signal during the first period, output a first comparison result of the ramp signal and the test signal, receive the pixel signal and the ramp signal from the signal selector during the second period, and output a second comparison result of the pixel signal and the ramp signal.

13. The analog-to-digital conversion circuit of claim 12, wherein
the signal selector includes a multiplexer configured to receive the pixel signal and the test signal, output the test signal during the first period, and output the pixel signal during the second period.

14. The analog-to-digital conversion circuit of claim 12, further comprising:
a counter circuit configured to output a first counting result based on the first comparison result during the first period and output a second counting result based on the second comparison result during the second period.

15. The analog-to-digital conversion circuit of claim 12, wherein
the comparison circuit includes a first comparator configured to receive the ramp signal as a first ramp signal during the first period, and output a first comparison result, and a second comparator configured to receive a second ramp signal different from the first ramp signal during the first period, and output a third comparison result of the second ramp signal and the test signal.

16. The analog-to-digital conversion circuit of claim 15, wherein
the first comparator is configured to output the first comparison result during the second period, and
the second comparator is configured to output a third comparison result of the pixel signal and the second ramp signal having a slope different from the slope of the first ramp signal during the second period.

17. A method of operating an image sensor, comprising:
measuring a second ramp signal having a first level based on a first ramp signal increasing or decreasing with a constant slope;
determining a compensation value of the first ramp signal based on a measurement result of the second ramp signal;
receiving a pixel signal from a pixel array; and
generating image data based on the first ramp signal and the pixel signal compensated with the compensation value.

18. The method of operating an image sensor of claim 17, further comprising:
measuring the second ramp signal having a second level different from the first level based on the first ramp signal.

19. The method of operating an image sensor of claim 18, wherein
the receiving the pixel signal includes
receiving a first pixel signal from a first pixel and receiving a second pixel signal from a second pixel, and
the generating the image data includes
generating first image data based on the first pixel signal and the first ramp signal and generating second image data based on the second pixel signal and the second ramp signal.

20. The method of operating an image sensor of claim 17, wherein
the measuring the second ramp signal and the receiving the pixel signal are performed in different periods.
